(19) United States
(12) Patent Application Publication
(10) Pub. No.: US 2013/0343415 A1
(43) Pub. Date: Dec. 26, 2013

(54) SURFACE EMITTING LASER

(71) Applicant: CANON KABUSHIKI KAISHA, Tokyo (JP)

(72) Inventors: Yuichiro Hori, Kawasaki-shi (JP); Aihiko Numata, Inagi-shi (JP)

(21) Appl. No.: 13/922,545

(22) Filed: Jun. 20, 2013

(30) Foreign Application Priority Data
Jun. 22, 2012 (JP) 2012-140591

(51) Int. Cl. H01S 5/18

(52) U.S. Cl. CPC H01S 5/18
USPC 372/38.05

(57) ABSTRACT

A surface emitting laser includes an active layer; a periodic-structure layer including a low-refractive-index medium and a high-refractive-index medium and whose refractive index varies periodically, the periodic-structure layer being provided at a position where light emitted from the active layer couples therewith; and a pair of electrodes from which electricity is supplied to the active layer. The periodic-structure layer is patterned as a square periodic-structure lattice. At least one of the electrodes includes one or more linear electrodes. A direction of each lattice vector of the periodic structure and a longitudinal direction of the linear electrodes are different from each other.

### BACKGROUND OF THE INVENTION

1. Field of the Invention

One disclosed aspect of the embodiments relates to a surface emitting laser.

2. Description of the Related Art

In recent years, researches in surface emitting lasers have been made energetically. Surface emitting lasers (also abbreviated to SEL) are advantageous in terms of easiness in integration and array formation, being less cost-consuming and highly reliable, having superior efficiency in coupling with external optical systems, and other aspects, and are therefore expected to be applied to various fields including communications, electrophotography, and sensing.

Surface emitting lasers have already been in practical use in the field of communications such as short-distance infrared communications. Among several types of surface emitting lasers, some surface emitting lasers function as resonators, in each of which a periodic structure includes a low-refractive-index medium and a high-refractive-index medium that are configured such that the refractive index of the structure varies periodically.

In such a surface emitting laser, light that is made to resonate and oscillate in a direction parallel to a substrate is diffracted in a direction perpendicular to the substrate and is extracted to the outside, whereby a surface emitting function is provided. Such a laser is categorized as a distributed-feedback (DFB) laser, which is widely used at present.

Japanese Patent Laid-Open No. 2009-206157 discloses an exemplary surface emitting laser that utilizes an effect of diffraction produced by a photonic crystal layer, and a method of manufacturing such a laser.

In this laser, which is a semiconductor laser, a photonic crystal layer is provided near an active layer, and light generated in the active layer is made to oscillate in an in-plane direction by utilizing an effect of second diffraction caused by the photonic crystal layer.

Furthermore, the light thus made to oscillate is extracted to the outside in a direction perpendicular to the in-plane direction by utilizing an effect of first diffraction caused by the photonic crystal layer.

Such a surface emitting laser is often discussed focusing on its characteristic as a large-area coherent light source. Therefore, a p-electrode employed in the surface emitting laser tends to have a large area, correspondingly.

### SUMMARY OF THE INVENTION

According to a first aspect of the embodiments, a surface emitting laser includes an active layer; a periodic-structure layer including a low-refractive-index medium and a high-refractive-index medium and whose refractive index varies two-dimensionally and periodically, the periodic-structure layer being provided at a position where light emitted from the active layer couples therewith; and a pair of electrodes from which electricity is supplied to the active layer. The periodic-structure layer is patterned as a square periodic-structure lattice. At least one of the electrodes includes one or more linear electrodes. A direction of each lattice vector of the periodic structure and a longitudinal direction of the linear electrodes are different from each other.

According to a second aspect of the embodiments, a surface emitting laser includes an active layer; a periodic-structure layer provided at a position where light emitted from the active layer couples therewith and including a low-refractive-index medium and a high-refractive-index medium; and a pair of electrodes from which electricity is supplied to the active layer. The periodic-structure layer is patterned as a square periodic-structure lattice. At least one of the electrodes includes island electrodes arranged in a pattern that is reverse to a lattice pattern formed by two or more lines extending in each of two directions. A direction of each lattice vector of the periodic structure and a direction of each lattice vector of the lattice pattern of the island electrodes are different from each other.

Further features of the disclosure will become apparent from the following description of exemplary embodiments with reference to the attached drawings.

### BRIEF DESCRIPTION OF THE DRAWINGS

FIGS. 1A to 1C illustrate a configuration of a surface emitting laser according to a first general embodiment. FIG. 1A illustrates a schematic sectional view illustrating major elements included in the surface emitting laser. FIG. 1B illustrates a sectional view of the laser taken in an xy plane extending along line IB-IB illustrated in FIG. 1A. FIG. 1C illustrates a sectional view of the laser taken in an xy plane extending along line IC-IC illustrated in FIG. 1A.

FIGS. 2A to 2C illustrate a mechanism of improving the thermal characteristic of the surface emitting laser according to the first general embodiment. FIG. 2A schematically illustrates a relationship between upper contact electrodes and the temperature distribution of an active layer provided below the electrodes. FIG. 2B illustrates insulating members provided in a stripe pattern as current-noninjectable regions. FIG. 2C illustrates current-noninjectable regions provided in an upper contact electrode.

FIGS. 3A and 3B illustrate the isotropy and the uniformity in gain obtained in the first general embodiment. FIG. 3A illustrates a positional relationship between the photonic crystal lattice and the electrodes arranged in a stripe pattern. FIG. 3B illustrates a positional relationship between the photonic crystal lattice and the electrodes arranged in another pattern.

FIGS. 4A and 4B illustrate the isotropy and the uniformity in gain obtained in the first general embodiment. FIG. 4A illustrates an arrangement of a group of upper contact electrodes in a stripe pattern and a photonic crystal lattice. FIG. 4B illustrates a photonic crystal region.

FIGS. 5A to 5C illustrate different patterns of upper contact electrodes according to the first general embodiment. FIG. 5A illustrates linear upper contact electrodes provided in such a manner as to extend in two directions that intersect each other. FIG. 5B illustrates upper contact electrodes provided in a pattern that is reverse to the lattice pattern. FIG. 5C illustrates a schematic sectional view mainly illustrating an upper portion of a laser including an active layer and layers provided thereabove.

FIG. 6 illustrates exemplary patterns of electrodes included in a surface emitting laser according to a second general embodiment.

FIGS. 7A to 7C illustrate a configuration of a surface emitting laser according to a first exemplary embodiment. FIG. 7A illustrates a sectional view of an overall configuration of the laser. FIG. 7B illustrates a sectional view of the laser taken in an xy plane extending along line VIIB-VIIB illustrated in FIG. 7A. FIG. 7C illustrates a sectional view of the laser taken in an xy plane extending along line VIIC-VIIC illustrated in FIG. 7A.

FIGS. 8A to 8C illustrate a configuration of a surface emitting laser according to a third exemplary embodiment. FIG. 8A illustrates a schematic sectional view mainly illustrating an upper portion of the laser according to the third exemplary embodiment. FIG. 8B illustrates a sectional view of the laser taken in an xy plane extending along line VIIIB-VIIIB illustrated in FIG. 8A. FIG. 8C illustrates a sectional view of the laser taken in an xy plane extending along line VIIIB-VIIIB illustrated in FIG. 8A.

FIGS. 9A and 9B illustrate a configuration of a surface emitting laser according to a fourth exemplary embodiment. FIG. 9A illustrates a schematic sectional view mainly illustrating an upper portion of the laser according to the fourth exemplary embodiment. FIG. 9B illustrates a sectional view of the laser taken in an xy plane extending along line IXB-IXB illustrated in FIG. 9A.

### DESCRIPTION OF THE EMBODIMENTS

In a laser including a large-area electrode, heat tends to concentrates immediately below a central portion of the electrode, increasing the temperature of an active layer. Hence, there is room for further improvement in terms of the thermal characteristic of the laser.

To solve such a problem, it has been found effective that the electrode does not have a uniformly planar shape and includes any current-noninjectable (or less-injected) regions.

In the current-noninjectable regions, resonant light has no gain. Unless the current-noninjectable regions are designed carefully, the regions may influence laser oscillation.

A two-dimensional photonic crystal laser generates light mainly containing components that resonate in two directions in the layer of the photonic crystal structure. Unless the gains in such resonant light components are isotropic and spatially uniform to some extent, oscillation tends to occur one-dimensionally in a resonance mode in one of the two directions.

In light of the above, one embodiment provides a two-dimensional photonic-crystal surface emitting laser having an improved thermal characteristic and a reduced influence upon oscillation modes and in which the occurrence of, in particular, one-dimensional oscillation is suppressed.

Surface emitting lasers according to general embodiments will now be described.

### First General Embodiment

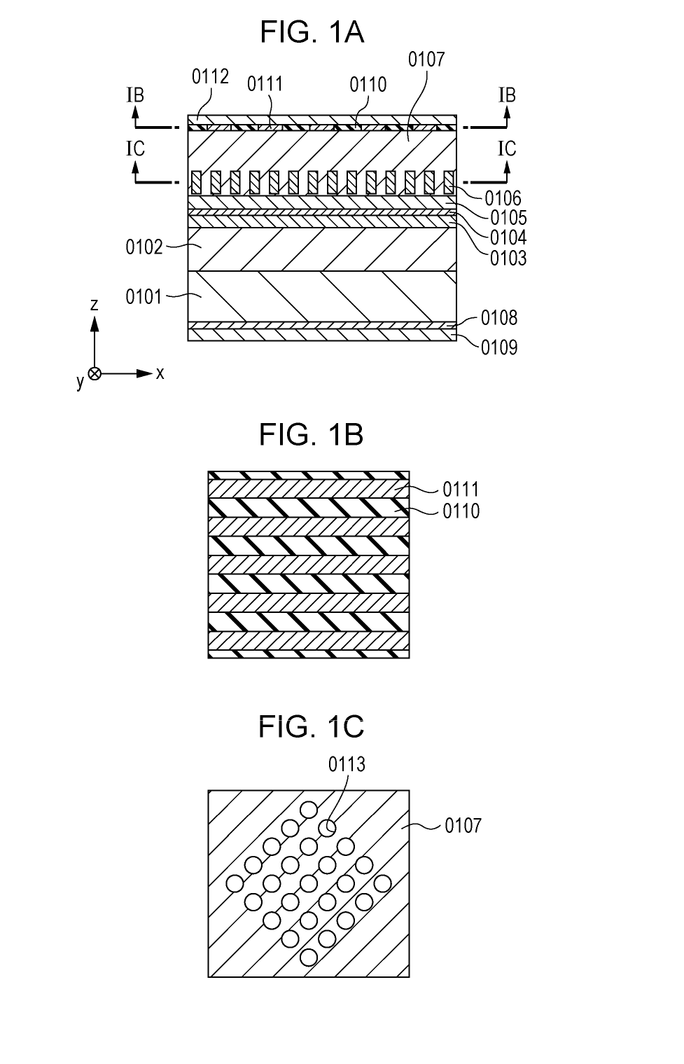

A configuration of a surface emitting laser according to a first general embodiment will be described with reference to FIGS. 1A to 1C.

FIG. 1A is a schematic sectional view illustrating major elements included in the surface emitting laser. The surface emitting laser according to the first general embodiment includes a substrate 0101, a lower cladding layer 0102, a lower light-guiding layer 0103, an active layer 0104, an upper light-guiding layer 0105, a photonic crystal layer 0106, and an upper cladding layer 0107 that are stacked in that order.

The surface emitting laser further includes a lower contact electrode 0108 and a lower pad electrode 0109 that are stacked in that order on the underside of the substrate 0101.

The surface emitting laser further includes insulating members 0110 and upper contact electrodes 0111 that are provided on the upper cladding layer 0107, and an upper pad electrode 0112 that is provided over the insulating members 0110 and the upper contact electrodes 0111. The insulating members 0110 and the upper contact electrodes 0111 are arranged alternately.

FIG. 1B is a sectional view of the laser taken in an xy plane extending along line IB-IB illustrated in FIG. 1A.

In the first general embodiment, as illustrated in FIG. 1B, the upper contact electrodes 0111 are arranged in a stripe pattern and are separated from one another by the insulating members 0110 interposed therebetween.

FIG. 1C is a sectional view of the laser taken in an xy plane extending along line IC-IC illustrated in FIG. 1A. The photonic crystal layer 0106 has photonic crystal holes 0113, thereby providing a photonic crystal lattice. The photonic crystal holes 0113 are arranged such that the direction of each lattice vector of the photonic crystal is different from the longitudinal direction of the upper contact electrodes 0111. In the first general embodiment, the photonic crystal layer 0106 thus having a periodic structure in which the refractive index thereof varies two-dimensionally and periodically is embedded in the upper cladding layer 0107.

The laser according to the first general embodiment is driven when a current is injected thereinto from a pair of n- and p-electrodes.

The first general embodiment is characterized in that the upper contact electrodes 0111 are linear electrodes that are arranged side by side in one direction into a stripe pattern as illustrated in FIG. 1B and such that the longitudinal direction thereof is different from the direction of each lattice vector of the photonic crystal.

At least one linear electrode is necessary. Preferably, two or more linear electrodes are to be provided. In such a configuration, the occurrence of one-dimensional oscillation with the photonic crystal lattice is suppressed while the thermal characteristic of the laser is improved.

Now, a mechanism of improving the thermal characteristic of the laser will be described.

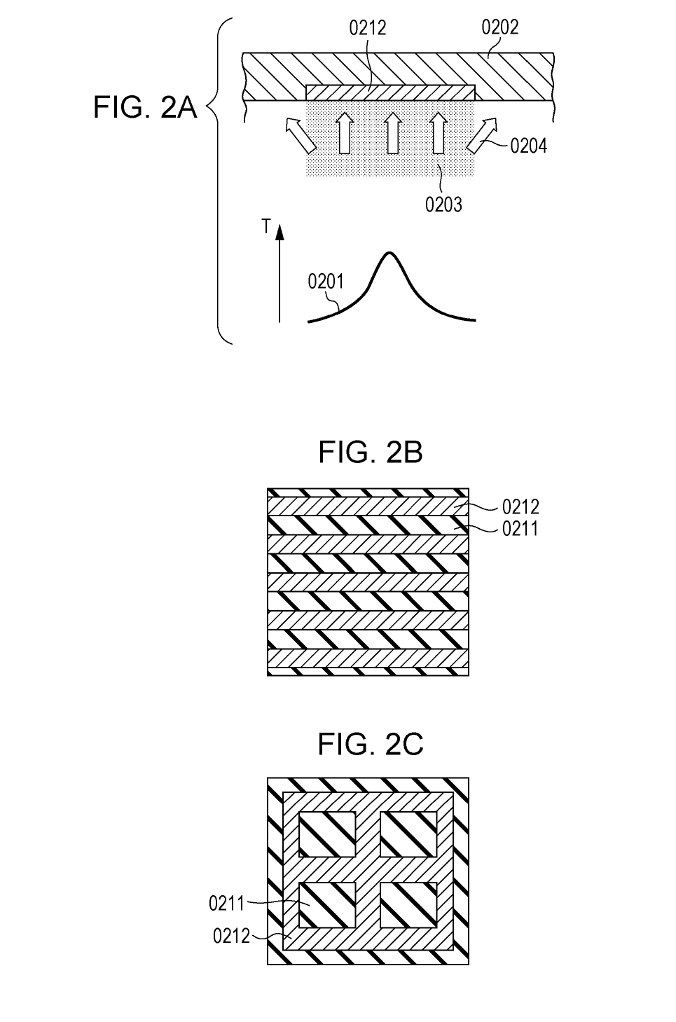

FIG. 2A schematically illustrates a relationship between upper contact electrodes 0212 and the temperature distribution of an active layer provided below the electrodes 0212. This relationship between the electrodes 0212 and the temperature of the active layer applies not only to a case of linear electrodes such as those illustrated in FIG. 1B but also to cases of any other electrodes that are employed in common lasers.

FIG. 2A illustrates the correspondence between a temperature distribution curve 0201 of the active layer and the position of each upper contact electrode 0212.

In this case, it is assumed that a pad electrode provided over the upper contact electrodes 0212 also functions as a heat sink 0202.

When electricity is supplied to each electrode 0212, the heat generating region 0203 generates heat. The heat generated by the 0203 diffuses toward the heat sink 0202 as illustrated by arrows that schematically represent heat flows 0204.

As represented by the temperature distribution curve 0201 in the lower part of FIG. 2A, the temperature of the active layer is highest in a region immediately below a central portion of the electrode 0212 and becomes lower toward the ends of the electrode 0212.

The heat thus generated diffuses like the heat flows 0204 before being discharged into the heat sink 0202. Therefore, the heat diffuses through to regions on the outer side of the ends of the electrode 0212 below which no heat is generated.

Hence, in terms of the balance between heat generation and heat discharge, the proportion of heat discharge to heat generation is greater in the regions on around the ends of the electrode 0212 than in the region below the central portion of the electrode 0212, resulting in the temperature distribution curve 0201.

This means that the more end portions an electrode has, the greater the heat dischargeability becomes and the more the thermal characteristic of the laser is improved. Although the heat flows 0204 are illustrated only by several arrows in FIG. 2A, heat is actually radiated from every position of the heat generating region 0203.

For the above reasons, if an electrode has a uniform current density, i.e., a uniform heat-generation density, it is advantageous in terms of heat radiation to increase the proportion of end portions in the electrode as much as possible by, for example, providing any nonconductive regions in the electrode rather than providing one square or circular electrode. For example, as illustrated in FIG. 2B, insulating members 0211 may be provided in a stripe pattern as current-noninjectable regions. Such a configuration exhibits improved heat dischargeability. Alternatively, as illustrated in FIG. 2C, current-noninjectable regions may be provided in an upper contact electrode 0212.

Note that the proportion of the total area of conductive regions to the heat diffusion needs to be determined carefully. For example, many fine current-noninjectable regions may be provided in an electrode as with radiating fins, whereby the total area of end portions in the electrode may be increased enormously. However, if the current-noninjectable regions are negligibly small relative to the heat diffusion, the intended effect is not produced.

The effective magnitude of heat diffusion is regarded as how much the heat generated when electricity is supplied to the electrode 0212 diffuses before being discharged into the heat sink, and depends on how far the heat generating region is from the heat sink.

In a case of a semiconductor laser, a portion thereof including an active layer and a p-type layer provided above the active layer functions as a heat source. In the configuration illustrated in FIG. 2A, the magnitude of heat diffusion is determined by the distance between the active layer as a heat generating region that is the farthest from the heat sink 0202 and the heat sink 0202.

Now, the isotropy and the uniformity in gain will be described.

In the cases of the electrodes 0212 illustrated in FIGS. 2B and 2C, although heat dischargeability is improved, another problem remains in that, since the distribution of optical gain varies correspondingly to the patterns of the electrodes 0212 and the positional relationship between the photonic crystal layer and the electrodes 0212, the influence upon oscillation also varies correspondingly.

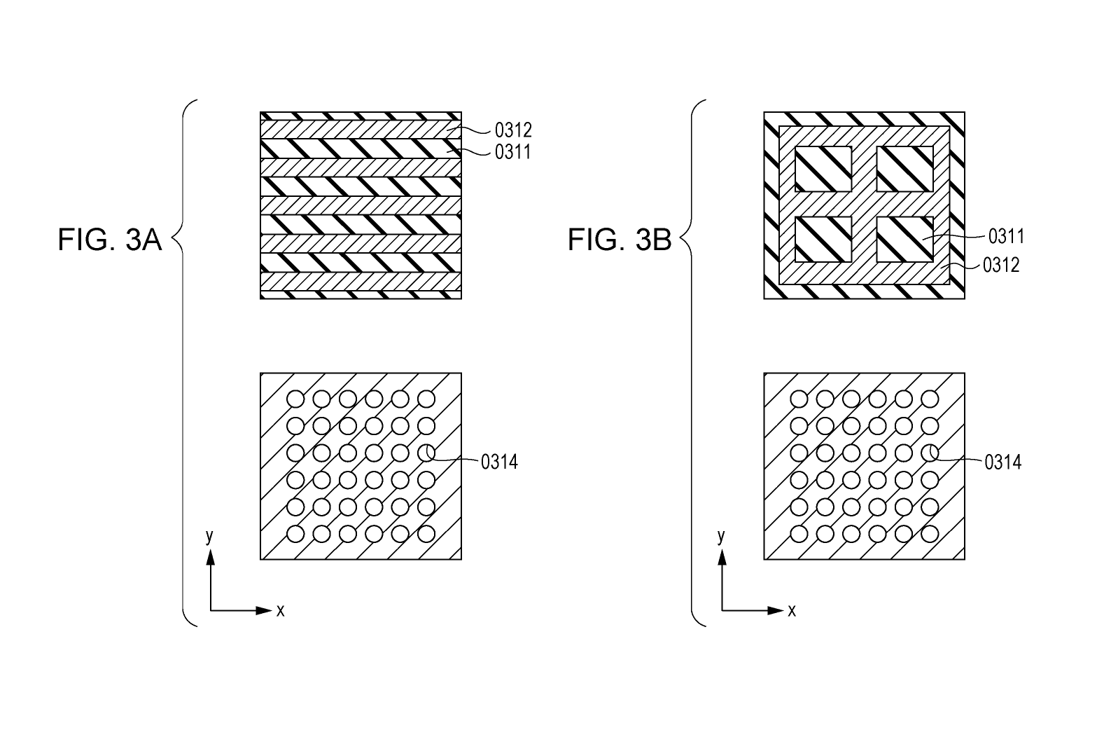

FIGS. 3A and 3B illustrate positional relationships between a square photonic crystal lattice and different electrodes 0312 corresponding to the electrodes 0212 illustrated in FIGS. 2B and 2C, respectively. In a photonic-crystal surface emitting laser (SEL), resonance mainly occurs in the x and y directions in FIGS. 3A and 3B for both a transverse-electric (TE) mode and a transverse-magnetic (TM) mode.

Hence, in the positional relationship between the photonic crystal lattice and the electrodes 0312 arranged in a stripe pattern illustrated in FIG. 3A, gain may increase only for resonance that occurs in one direction, that is, only one-dimensional resonance in the x direction may occur only in regions immediately below the electrodes 0312.

In the positional relationship between the photonic crystal lattice and the electrodes 0312 arranged in the pattern illustrated in FIG. 3B, gain may increase locally in each of the x and y directions only for resonance that occurs in one direction, and one-dimensional resonance in each of the x and y directions may occur only in regions immediately below the electrode 0312.

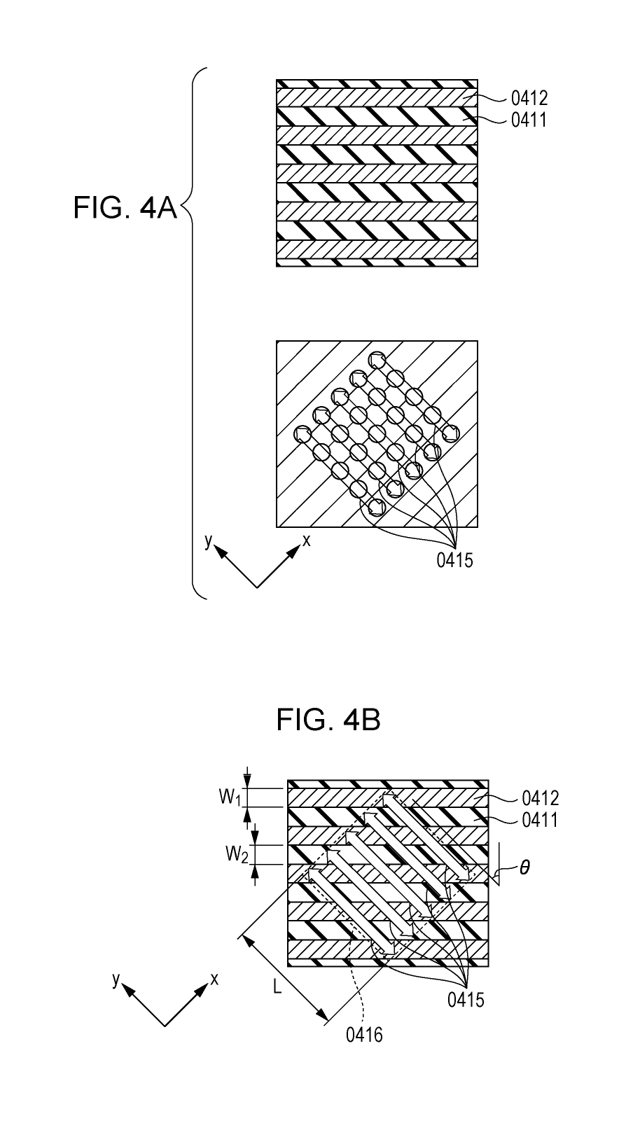

Hence, an exemplary configuration illustrated in FIG. 4A is employed in which a group of upper contact electrodes 0412 in a stripe pattern and a photonic crystal lattice are arranged such that the longitudinal direction of the electrodes 0412 is different from the direction of each lattice vector of the photonic crystal.

In such a configuration, focusing on resonance 0415 in the y direction illustrated in FIG. 4A, the anisotropy of gain in resonant light is eased.

Furthermore, the variation in the amount of gain in resonant light produced over the entirety of a range from one end to the other end, in the x direction, of a region where the photonic crystal lattice is provided (hereinafter referred to as photonic crystal region) is reduced spatially. This also applies to resonance in the x direction in the same way.

If the angle formed between the longitudinal direction of the electrodes 0412 and the direction of each lattice vector of the photonic crystal is set to 45°, gain becomes isotropic and uniform for resonant light in all directions of the lattice. Such a configuration is defined as a situation where gain in resonant light is spatially uniform. By employing this configuration, the occurrence of one-dimensional oscillation is prevented while heat dischargeability is improved.

It is preferable that gain is uniform at every position in a direction of resonance.

In this respect, it is preferable the pitch of electrodes are as fine as possible. However, if the pitch of electrodes is reduced extremely, the group of electrodes are regarded as a simple flat-plate electrode. Therefore, the reduction in the pitch of electrodes is limited to some extent. Even a relatively large pitch of electrodes can produce the intended effect if parameters, such as coupling coefficient which represents the degree of diffraction of light and absorptance, are adjusted appropriately.

Although the upper contact electrodes 0412 illustrated in FIG. 4A are arranged in a periodic stripe pattern, the electrodes 0412 are not necessarily arranged periodically.

Usually, the term “lattice vector” is used for a lattice having a periodic structure. Herein, the scope of the term “lattice vector” is widened so as to encompass any vectors along which electrodes are arranged.

Now, the angle formed between the photonic crystal lattice and each upper contact electrode according to the first general embodiment will be described. In the first general embodiment, it is preferable that optical gain is isotropic as much as possible in both of the two directions of resonance. Therefore, an angle θ formed between the direction of each lattice vector of the photonic crystal and the longitudinal direction of the electrode is most preferably 45°, as described above.

Even if the angle θ is not 45°, the intended effect is produced unless the longitudinal direction of the electrode is the same as the direction of each lattice vector of the photonic crystal (that is, unless the angle θ is zero).

The angle θ formed between the direction of each lattice vector of the photonic crystal and the longitudinal direction of the electrode preferably falls within a range between 45°±22.5° (22.5°≦θ≦67.5°, and the angle 22.5° is the half angle between 45° and 0°). More preferably, the angle θ is 35°≦θ≦55°. Yet more preferably, the angle θ is 40°≦θ≦50°.

The width and the pitch of the electrodes arranged in a stripe pattern according to the first general embodiment are designed from viewpoints of heat and light.

Guidelines for designing the width and the pitch of the electrodes according to the first general embodiment are given below.

First, guidelines from a viewpoint of heat will be described.

In terms of heat dischargeability, the width of the electrodes is desired to be as small as possible. Needless to say, however, electrodes that are so thin as to significantly increase the resistance are not preferable.

As the electrodes are made thinner, practical processing conditions for fabricating the electrodes become stricter.

In terms of heat dischargeability, the pitch of the electrodes is desired to be as large as possible.

If the pitch of the electrodes exceeds a certain value, however, substantially no thermal interference occurs between the electrodes, that is, the electrodes are regarded as being substantially independent of one another. Therefore, increasing the pitch of the electrodes to a value larger than that certain value produces no further advantageous effect on the performance of the laser.

Letting the distance between the heat sink and the active layer be d, the above certain pitch is preferably 4d, or more preferably 8d, or yet more preferably 12d according to simulations and other factors.

Next, design guidelines from a viewpoint of optical coupling will be described.

Light emitted from a region of the active layer immediately below a certain electrode propagates through the active layer while being diffracted and absorbed.

In a case where the degree of diffraction relative to the pitch of the electrodes is large and the light emitted from the active layer is totally redirected by diffraction, or is totally absorbed before reaching a region below an adjacent electrode, the light beams emitted from respective regions below the electrodes that are adjacent to each other may not couple with each other and may oscillate locally.

To avoid such a situation, the pitch of the electrodes needs to be as small as possible.

In a design policy, the pitch and the width of the electrodes need to be adjusted so as not to become too large relative to the degrees of diffraction and absorptance.

Now, other guidelines for designing the electrodes will be described.

Parameters of the linear electrodes according to the first general embodiment can be set as follows.

As described above, the anisotropy in the amount of gain in resonant light produced over the entirety of a range from one end to the other end of the photonic crystal region is desired to be small, and more preferably the gain is completely uniform over the entirety of the range.

FIG. 4B illustrates a photonic crystal region 0416, which is also illustrated in the lower part of FIG. 4A, represented by dotted lines over a region in which the electrodes 0412 are provided. To make the amount of gain in resonant light uniform over the entirety of the photonic crystal region, the sum of the lengths of portions of the electrodes 0412 that are present above a region where each of the resonant light propagating in the x and y directions passes through is made uniform over the entirety of the photonic crystal region 0416.

In such a case, ends of electrodes 0412 reside at positions on opposite sides of the photonic crystal region 0416, geometrically. In this manner, the sum of the lengths of portions of the electrodes 0412 that are present above the region where each of the resonant light propagating in the x and y directions passes through becomes uniform advantageously over the entirety of the photonic crystal region 0416.

Assume that the electrodes 0412 are provided periodically, the electrodes 0412 each have a width W₁ and are arranged at a pitch W₂, and the photonic crystal region 0416 is a square of side L.

Further assume that the longitudinal direction of the electrodes 0412 and the direction of each lattice vector of the square photonic crystal form an angle of 45° therebetween. Here, the following expression needs to be satisfied:

√2N(W₁+W₂)=L,where N is a positive integer.

In the first general embodiment, upper contact electrodes are arranged in a stripe pattern. Upper contact electrodes having other configurations are also acceptable.

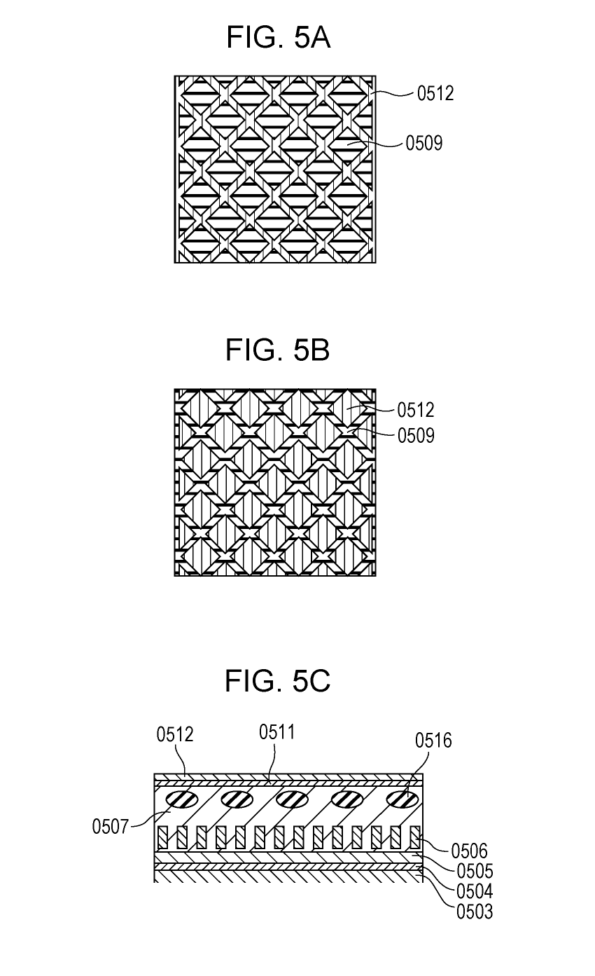

For example, as illustrated in FIG. 5A, linear upper contact electrodes 0512 may be provided in such a manner as to extend in two directions that intersect each other, thereby forming a lattice pattern. In such a configuration, insulating members 0509 each having a square or rectangular shape are provided as illustrated in FIG. 5A. If the linear electrodes 0512 arranged periodically in the two directions are made to intersect at an angle other than 90°, the insulating members 0509 each have a diamond or parallelogram shape. In the case where the electrodes 0512 are arranged in a lattice pattern, two groups of electrodes 0512 extending in the two respective directions that intersect each other may be arranged either at the same pitch or at different pitches.

Alternatively, as illustrated in FIG. 5B, upper contact electrodes 0512 may be provided in a pattern that is reverse to the lattice pattern. That is, upper contact electrodes 0512 may be island electrodes each having a square, oblong rectangle, parallelogram, or dot shape.

In such a case, however, the extent of the intended effect is lowered in terms of the uniformity in in-plane gain.

In each of the above and the following embodiments, the configuration of the laser may be changed in the direction in which layers of the laser are stacked.

FIG. 5C is a schematic sectional view mainly illustrating an upper portion of a laser including an active layer 0504 and layers provided thereabove. Compared with the configuration of the laser illustrated in FIG. 1A, the laser illustrated in FIG. 5C additionally includes insulating regions 0516 provided between the active layer 0504 and an upper contact electrode 0511.

The laser illustrated in FIG. 5C is also regarded as a laser having the configuration illustrated in FIG. 1A with the insulating members 0110 embedded into an internal layer of the laser. Essentially, the embodiment is realized if the paths along which a current is injected (i.e., the heat sources) are arranged in a pattern conforming to any of the electrode patterns described above.

Hence, the upper contact electrode 0511 of a sheet type is also acceptable. Instead, the insulating regions 0516 each having a linear shape as described above and that are provided below the electrode 0511 are arranged in a stripe, lattice, or any other pattern, whereby current paths arranged in that pattern are provided. In such a manner, the intended effect of the embodiment is produced.

In such a case, however, since heat generated with the supply of electricity in the entirety of the laser propagates up to the insulating regions 0516, the thermal characteristic of the laser is inferior to that of the laser according to the first general embodiment. In addition, the resistance of the laser tends to increase.

The laser according to the first general embodiment can employ any layer configuration that is applicable to common semiconductor lasers.

Typically, an active layer is held between light guiding layers, adjacent to which cladding layers are provided, respectively. The active layer can have a single- or multiple-quantum-well structure, a quantum-dot structure, or the like.

A current blocking layer may be added into any of the light guiding layers and the cladding layer or at any interface therebetween.

In a case of a compound semiconductor laser, a highly doped contact layer can be provided below a p-side contact electrode so that the electrical contact with the electrode is improved.

In the laser according to the first general embodiment, no current is directly injected from the driving electrodes, i.e., the upper contact electrodes, into regions between the driving electrodes. Therefore, some light absorption loss due to the active layer occurs in the those regions.

To avoid this, portions of the active layer that are present immediately below the regions into which no current is injected, i.e., portions of the active layer below the insulating members 0509 or the insulating regions 0516 according to the first general embodiment, may be removed so that light absorption does not occur.

To do so, the process of manufacturing the laser may be complicated with the addition of a step of removing portions of the active layer, a step of regrowing crystal performed thereafter, and other steps. Nevertheless, light absorption is reduced, advantageously lowering the threshold current.

The first general embodiment employs a square photonic crystal lattice. Alternatively, an oblong rectangular photonic crystal lattice, which is one of quadrilateral lattices, may be employed.

In the first general embodiment, the photonic crystal lattice is composed of holes which are provided in a solid medium. The photonic crystal lattice only needs to have a periodic-refractive-index structure composed of a low-refractive-index medium and a high-refractive index medium, and may have a configuration in which the positions of the holes and the solid medium are reversed or a configuration in which a medium having a refractive index different from that of a base medium is injected into the base medium in the position of the holes.

As illustrated in FIG. 2A, as the heat generating region 0203 as a conductive region becomes smaller relative to the spreading of heat flows toward the heat sink 0202 as a heat radiating member, the extent of improvement in the thermal characteristic realized in the first general embodiment becomes higher. This is because, if so, the area of the heat radiating region becomes larger relative to the heat generating region.

In contrast, if the current spreads widely, the current is distributed almost uniformly, deteriorating the effect of the embodiment, even if current paths are formed by using, for example, the electrodes 0212 illustrated in FIG. 2B.

Accordingly, in the first general embodiment, the effects of the embodiment are more likely to be produced if the upper cladding layer 0507 illustrated in FIG. 5C has a relatively high resistance so that the spreading of the current is suppressed.

Practically, in a case of a semiconductor laser, it is preferable that any of the electrodes described in the first general embodiment are provided on the p-side, in which resistance is high.

The photonic crystal lattice needs to be provided in a region where the current flowing therethrough is not uniform. Accordingly, in a case of a compound semiconductor laser, it is preferable that the photonic crystal lattice is also provided on the p-side.

If the resistance is high, a large amount of heat is generated. Therefore, it is not desirable to intentionally increase the resistance. Every semiconductor laser includes a p-layer. Hence, in the first general embodiment, any of the above electrode configurations is employed for the purpose of utilizing the high resistance of the p-layer.

To increase the efficiency in extraction of light, it is preferable that the materials for members (the insulating members 0110, the upper contact electrodes 0111, and the upper pad electrode 0112 in the first general embodiment) that are present in the paths through which light is emitted each have a high transmittance with respect to the wavelength of light to be generated. For example, in terms of transmittance, a material such as SiO₂ or Si₃N₄ may be employed as the insulating members 0110. Furthermore, in terms of transmittance, a transparent electrode composed of a material such as ITO may be employed as the electrodes 0111.

In the first general embodiment, a mounting method by which the advantageous effect of the disclosed embodiment is exerted most is a so-called junction-down mounting, in which the upper electrodes are directly brought into contact with a heat radiating member.

Another method in which a side of the laser having the substrate is brought into contact with a heat radiating member is also acceptable, as with the method employed for typical semiconductor lasers. In this method, the advantageous effect of the embodiment is reduced, though.

### Second General Embodiment

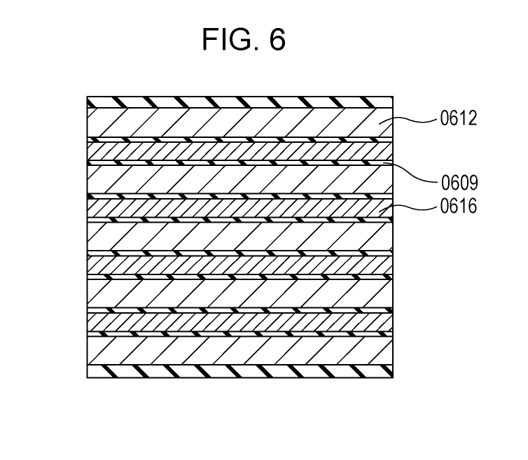

A configuration of a surface emitting laser according to a second general embodiment will now be described with reference to FIG. 6.

In the second general embodiment, auxiliary electrodes for reducing light absorption by the active layer are additionally provided as second electrodes between the upper contact electrodes (first electrodes), which are provided for driving the laser, described in the first general embodiment.

As illustrated in FIG. 6, the surface emitting laser according to the second general embodiment includes absorption-reducing contact electrodes 0616 provided between upper driving contact electrodes 0612.

In the second general embodiment, to reduce light absorption loss due to the active layer that may occur in regions into which the current from the upper driving contact electrodes 0612 is not directly injected, a current at such a low density needed for reducing or eliminating light absorption by the active layer is injected from the absorption-reducing contact electrodes 0616.

The current to be injected here has a far lower density than the current used for driving. Therefore, the amount of heat generated by the low-density current is also far smaller than the heat generated by the driving current.

The absorption-reducing contact electrodes 0616 according to the second general embodiment are also applicable to cases where the upper driving contact electrodes 0612 are arranged in other patterns that are employed in the first general embodiment (such as a lattice pattern or a reverse lattice pattern).

If applied to such cases, the absorption-reducing contact electrodes 0616 are provided in regions the upper contact electrodes described in the first general embodiment are not provided.

In the second general embodiment, if any high-resistance portions are provided in the upper driving contact electrodes 0612, an effect that is equivalent to the effect produced with the absorption-reducing contact electrodes 0616 is produced.

In the first exemplary configuration described in the second general embodiment, currents are injected from the upper driving contact electrodes 0612 and the absorption-reducing contact electrodes 0616 independently. In the case where any high-resistance portions are provided in the upper driving contact electrodes 0612, the current injection density in the high-resistance portions is reduced. Therefore, an effect that is equivalent to the effect produced with the absorption-reducing contact electrodes 0616 is produced.

Such high-resistance portions can be provided by, for example, weakly oxidizing the upper driving contact electrodes 0612 or increasing the resistance of the upper driving contact electrodes 0612 through doping of impurities.

In the second general embodiment, if any low-current-injection-density regions are provided in the laser device itself, the intended effect can also be produced.

Such a configuration is realized by, in the configuration according to the first general embodiment that is illustrated in FIG. 5C, reducing the resistance of the insulating regions 0516 to such a level that the insulating regions 0516 function as high-resistance regions, not as complete insulators. In this case, first regions having a high current density and second regions having a low current density can be provided as current injection regions.

In such a configuration, the current is injected over the entirety of the laser before reaching the high-resistance regions provided in the laser. Therefore, the effect produced is smaller than in a case where absorption-reducing electrodes are provided or in a case where the injection is controlled on the basis of the resistance of the driving electrodes.

Both the high-resistance portions of the upper contact electrodes and the high-resistance regions embedded in the laser are intended for controlling the current injection regions and are therefore each arranged in a pattern corresponding to the absorption-reducing contact electrodes 0616 illustrated in FIG. 6.

### EXEMPLARY EMBODIMENTS

Exemplary embodiments will now be described.

### First Exemplary Embodiment

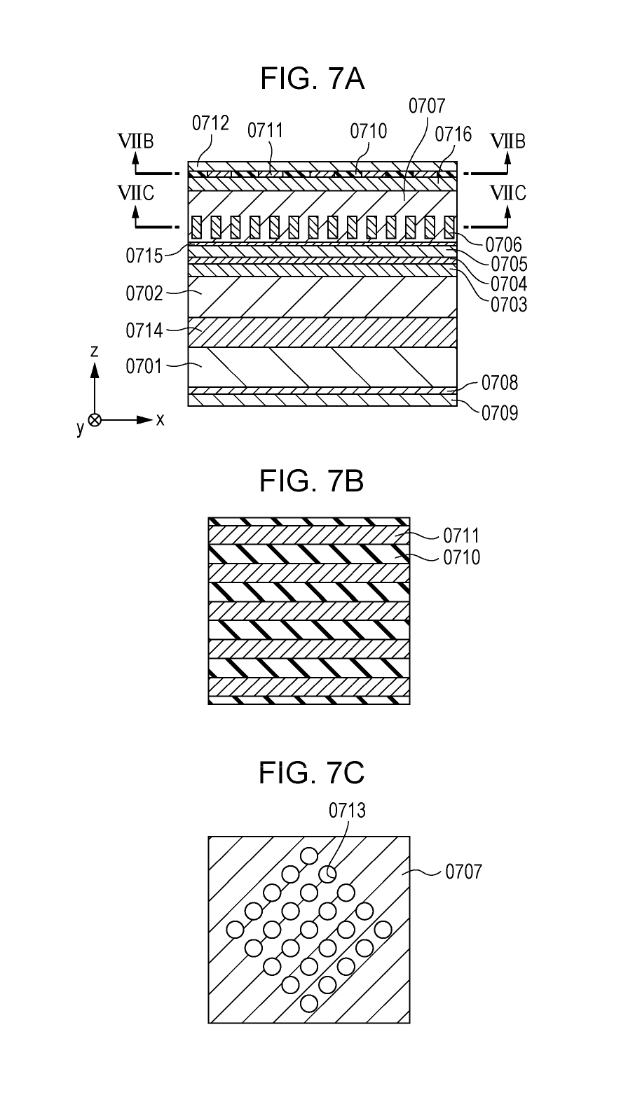

A configuration of a surface emitting laser according to a first exemplary embodiment will be described with reference to FIGS. 7A to 7C.

FIG. 7A is a sectional view illustrating an overall configuration of the laser.

The laser includes a substrate 0701 and an underlayer 0714 provided on the substrate 0701.

The laser further includes a lower cladding layer 0702, a lower light-guiding layer 0703, an active layer 0704, an upper light-guiding layer 0705, an electron blocking layer 0715, a photonic crystal layer 0706, an upper cladding layer 0707, and a contact layer 0716 that are stacked in that order on the underlayer 0714.

The laser further includes a lower contact electrode 0708 and a lower pad electrode 0709 that are stacked in that order on the underside of the substrate 0701.

The laser further includes insulating members 0710 and upper contact electrodes 0711 that are provided alternately on the contact layer 0716, and an upper pad electrode 0712 provided over the insulating members 0710 and the upper contact electrodes 0711.

FIG. 7B is a sectional view of the laser taken in an xy plane extending along line VIIB-VIIB illustrated in FIG. 7A.

In the first exemplary embodiment, as illustrated in FIG. 7B, the upper contact electrodes 0711 are arranged in a stripe pattern and are separated from one another by the insulating members 0710 interposed therebetween.

FIG. 7C is a sectional view of the laser taken in an xy plane extending along line VIIC-VIIC illustrated in FIG. 7A.

The photonic crystal layer 0706 has photonic crystal holes 0713, thereby forming a square photonic crystal lattice. The photonic crystal holes 0713 are arranged such that the direction of each lattice vector is at 45° with respect to the longitudinal direction of the upper contact electrodes 0711.

In the first exemplary embodiment, the members included in the laser are composed of gallium-nitride (GaN)-based materials. The substrate 0701 is composed of n-type GaN and has a thickness of 400 μm.

The underlayer 0714 is composed of n-type GaN and has a thickness of about 6 μm. The lower cladding layer 0702 is composed of n-type Al_{0.07}Ga_{0.93}N and has a thickness of 800 nm. The lower light-guiding layer 0703 is composed of n-type GaN and has a thickness of 80 nm.

The active layer 0704 has a multiple-quantum-well structure composed of InGaN and GaN. The structure includes a well layer composed of In_{0.1}Ga_{0.9}N and having a thickness of 3 nm, and a barrier layer composed of GaN and having a thickness of 5 nm. The structure includes three wells. The active layer is an undoped layer.

The upper light-guiding layer 0705 is composed of undoped GaN and has a thickness of 80 nm. The electron blocking layer 0715 is composed of p-type Al_{0.2}Ga_{0.8}N and has a thickness of 20 nm. The photonic crystal layer 0706 is embedded in the upper cladding layer 0707 and has a thickness of 240 nm. The upper cladding layer 0707 is composed of p-type Al_{0.07}Ga_{0.93}N and has a thickness of 350 nm.

The lower end of the photonic crystal layer 0706 is 70 nm above the electron blocking layer 0715. The contact layer 0716 provided above the upper cladding layer 0707 is composed of highly doped p-type GaN and has a thickness of 110 nm.

The layers composed of n-type GaN and n-type AlGaN are doped with Si at respective densities of 3×10¹⁹ cm⁻¹ and 2×10¹⁹ cm⁻¹. The layers composed of p-type AlGaN and highly doped p-type GaN are doped with Mg at respective densities of 2×10¹⁹ cm⁻¹ and 1×10²⁰ cm⁻¹.

The insulating members 0710 are composed of SiO₂ and each have a thickness of 80 nm.

The lower contact electrode 0708 includes layers composed of Ti and Al, respectively, stacked in that order on the underside of the substrate 0701. The Ti layer and the Al layer have respective thicknesses of 10 nm and 20 nm. The lower pad electrode 0709 includes layers composed of Ti and Au, respectively. The Ti layer and the Au layer have respective thicknesses of 10 nm and 300 nm.

The upper contact electrodes 0711 each include layers composed of Ni and Au, respectively. The Ni layer and the Au layer have respective thicknesses of 10 nm and 40 nm.

The upper pad electrode 0712 includes layers composed of Ti and Au, respectively. The Ti layer and the Au layer have respective thicknesses of 30 nm and 400 nm. The photonic crystal layer 0706 forms a square lattice defined by the following parameters: a lattice constant of 160 nm, a hole diameter of 35 nm, and a hole depth of 240 nm. The lattice extends over a region in an xy plane of size 150 μm×150 μm.

The upper contact electrodes 0711 according to the first exemplary embodiment will now be described.

In the first exemplary embodiment, the upper contact electrodes 0711 are arranged in a stripe pattern. The upper contact electrodes 0711 each have a width of 2 μm and are arranged at a pitch of 6 μm.

When electricity is supplied to the laser according to the first exemplary embodiment, surface-emission laser light is generated.

The upper contact electrodes 0711 arranged in a stripe pattern are provided such that the longitudinal direction thereof is at 45° with respect to the direction of each lattice vector of the square photonic crystal. Therefore, the occurrence of one-dimensional laser oscillation is suppressed while the thermal characteristic (heat dischargeability) of the laser is improved.

Detailed reasons for the above effect have already been described in the general embodiments. As described above, the width of each upper contact electrode 0711 is desired to be as small as possible in terms of heat dischargeability. Practically, considering the difficulty in processing, the width of each upper contact electrode 0711 is preferably 5 μm or smaller and 1 μm or larger.

The pitch of the upper contact electrodes 0711 is desired to be as large as possible. When the pitch reaches a certain size, however, there is no further difference in the effect produced by increasing the size of the pitch.

In the first exemplary embodiment, the pitch of the upper contact electrodes 0711 only needs to be about 6 μm or larger.

From a view point of optical coupling, too large a width and a pitch of the upper contact electrodes 0711 are not preferable because light beams generated below the individual electrodes 0711 do not couple with each other.

Light is diffracted in accordance with coupling coefficient κ and light absorption coefficient α. To cause light beams to couple with each other, the pitch of the upper contact electrodes 0711 can be set to a value smaller than about 1/(κ+α).

Preferably, in the first exemplary embodiment, κ is 650 cm⁻¹ or smaller, α is 90 cm⁻¹ or smaller, and the period of upper contact electrodes 0711 is 14 μm or smaller.

The value of κ is adjustable in accordance with the design of the photonic crystal layer 0706.

To summarize, in the first exemplary embodiment, it is preferable that the width of the upper contact electrodes 0711 be 5 μm or smaller and 1 μm or larger and the pitch of the upper contact electrodes 0711 be 6 μm or larger and 14 μm or smaller. The parameters according to the first exemplary embodiment fall within the foregoing ranges.

Lastly, a method of manufacturing the laser according to the first exemplary embodiment will be described.

The laser according to the first exemplary embodiment is manufactured through layer forming steps including crystal growth and sputtering, patterning steps including photolithography and electron-beam (EB) lithography, etching steps including wet and dry etching, electrode forming steps including deposition and lift-off, and other steps.

First, an underlayer 0714, a lower cladding layer 0702, a lower light-guiding layer 0703, an active layer 0704, an upper light-guiding layer 0705, an electron blocking layer 0715, and a photonic crystal layer 0706 (having no holes yet) to be embedded in an upper cladding layer 0707 are grown on a GaN substrate by means of epitaxial crystal growth.

Subsequently, the photonic crystal layer 0706 is processed by EB lithography and dry etching, and crystal is then grown again, whereby a photonic crystal lattice is embedded in a layer forming a portion of the upper cladding layer 0707. Furthermore, the rest of the upper cladding layer 0707 and a contact layer 0716 are grown.

Subsequently, a lower contact electrode 0708 and upper contact electrodes 0711 are formed by photolithography, deposition, lift-off, and other methods. Then, the substrate 0701 is made thinner by grinding and polishing, the resulting body is cut into chips, and the chips are mounted, in a junction-down orientation, on a device holder composed of Cu and coated with Au film deposited thereon.

The mounting is performed by Au—Au bonding.

Although portions of the active layer 0704 that are present below positions between the upper contact electrodes 0711 are not removed in the first exemplary embodiment, the portions may be removed as described in the general embodiments.

In that case, a step of removing portions of the active layer 0704 that are present immediately below regions not having the upper contact electrodes 0711 is added. The portions to be removed depend on the pattern of the upper contact electrodes 0711. Specifically, the portions of the active layer 0704 are removed by photolithography and dry etching before forming the photonic crystal layer 0706, and crystal is grown again only in areas resulting from the removal until the crystal layer has the same thickness as the photonic crystal layer 0706.

After that, the same steps as for the method in which no portions of the active layer 0704 are removed are performed.

In the first exemplary embodiment, members forming the laser are composed of GaN-based materials such as GaN, InGaN, and AlGaN having specific composition ratios. Other materials having arbitrary composition ratios may alternatively be used.

Semiconductor materials that can be used for the laser include III-V compound semiconductors such as carrier-doped GaAs, AlGaAs, InP, GaAsInP, and AlGaInP, and mixed crystals containing any of the foregoing materials; II-VI compound semiconductors such as ZnSe, CdS, and ZnO, and mixed crystals containing any of the foregoing materials; and IV semiconductors such as Si and SiGe, and mixed crystals containing any of the foregoing materials.

Materials for the electrodes are also selectable in accordance with the materials for other members forming the laser, as with known technologies.

The materials listed above are also employed in any of other exemplary embodiments to be described below and the general embodiments described above.

### Second Exemplary Embodiment

A configuration of a surface emitting laser according to a second exemplary embodiment that is different from that of the first exemplary embodiment will now be described.

Upper electrodes according to the second exemplary embodiment are arranged in a lattice pattern such as the one illustrated in FIG. 5A. The second exemplary embodiment differs from the first exemplary embodiment only in the configuration of the upper electrodes. That is, the other configurations of the laser and the materials and manufacturing method employed in the second exemplary embodiment are all the same as those of the first exemplary embodiment.

In the case where the upper electrodes are arranged in a lattice pattern also, the electrodes can be designed on the basis of the same viewpoints as in the first exemplary embodiment.

Parameters (width and pitch) that define the electrodes are also the same as those employed in the first exemplary embodiment. Specifically, the width of the electrodes is 2 μm, and the pitch of the electrodes is 6 μm.

In the second exemplary embodiment, each lattice vector of the lattice of electrodes is at 45° with respect to each of lattice vector of the photonic crystal.

In the second exemplary embodiment, the density of electrodes is higher than that of the first exemplary embodiment employing electrodes arranged in a stripe pattern. Furthermore, there are local concentration of electrodes at intersections of the electrodes. Therefore, the second exemplary embodiment is disadvantageous to the first exemplary embodiment in terms of the thermal characteristic.

In the second exemplary embodiment, when the lattice of electrodes is regarded as a combination of two stripe patterns extending in two respective directions that are orthogonal to each other, the pitch and the width of the electrodes are each the same for both directions.

One of or both the pitch and the width of the electrodes arranged in the two stripe patterns extending in the respective directions may be varied.

In the second exemplary embodiment, the electrodes arranged in a lattice pattern such as the one illustrated in FIG. 5A are employed. Alternatively, as illustrated in FIG. 5B, the electrodes may be arranged in a pattern that is reverse to the lattice pattern (a pattern of squares, parallelograms, or dots).

In that case, the concept employed in the first exemplary embodiment also applies to the size and the pitch of the electrodes.

In the case of the electrodes arranged in a pattern that is reverse to a lattice pattern, the current is more likely to concentrate locally than in the case of the electrodes arranged in a lattice pattern. Hence, the performance in terms of the thermal characteristic is further limited.

### Third Exemplary Embodiment

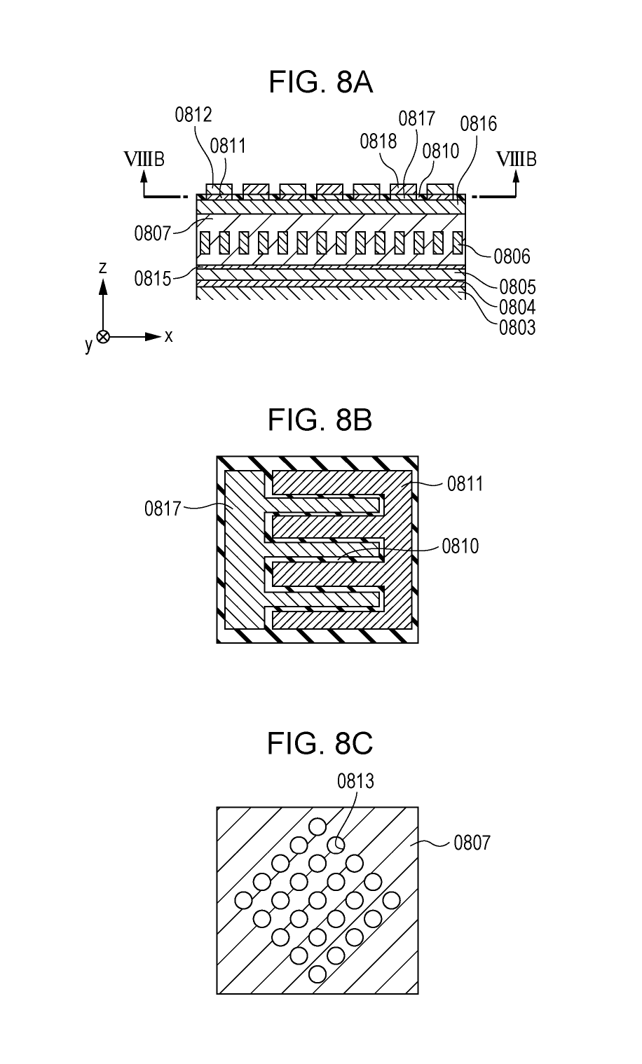

A configuration of a surface emitting laser according to a third exemplary embodiment that is different from that of the first exemplary embodiment will now be described with reference to FIGS. 8A to 8C.

FIG. 8A is a schematic sectional view mainly illustrating an upper portion of the laser according to the third exemplary embodiment including an active layer 0804 and layers provided thereabove. The laser according to the third exemplary embodiment includes the same layers, from lower electrodes (not illustrated) to a contact layer 0816, as those of the laser according to the first exemplary embodiment, except upper electrodes. That is to say, a lower light-guiding layer 0803, an active layer 0804, an upper light-guiding layer 0805, an electron blocking layer 0815, a photonic crystal layer 0806, an upper cladding layer 0807, and a contact layer 0816 are the same as the lower light-guiding layer 0703, the active layer 0704, the upper light-guiding layer 0705, the electron blocking layer 0815, a photonic crystal layer 0706, the upper cladding layer 0707, and the contact layer 0716, respectively.

The laser includes an upper driving contact electrode 0811 and an absorption-reducing contact electrode 0817 that are provided on the contact layer 0816. Segments of the upper driving contact electrode 0811 and segments of the absorption-reducing contact electrode 0817 extend alternately with an insulating member 0810 extending along the gaps therebetween.

An upper driving pad electrode 0812 is provided on the upper driving contact electrode 0811. An absorption-reducing pad electrode 0818 is provided on the absorption-reducing contact electrode 0817.

The driving electrodes 0811 and 0812 are for injection of a current into the laser so as to drive the laser to oscillate, and correspond to the upper contact electrodes 0711 and the upper pad electrode 0712 according to the first exemplary embodiment illustrated in FIG. 7A.

The absorption-reducing electrodes 0817 and 0818 are for reduction of light absorption in regions where the driving current generated between the driving electrodes 0811 and 0812 does not flow. The current to be injected from the absorption-reducing electrodes 0817 and 0818 is smaller than the current injected from the driving electrodes 0811 and 0812 so as not to noticeably contribute the increase in the temperature of the active layer 0804. That is, a small current for reducing light absorption is injected from the absorption-reducing electrodes 0817 and 0818.

The absorption-reducing contact electrode 0817 and the upper driving contact electrode 0811 are electrically independent of each other. Accordingly, the upper driving pad electrode 0812 and the absorption-reducing pad electrode 0818 are also independent of each other in the third exemplary embodiment.

FIG. 8B is a sectional view of the laser taken in an xy plane extending along line VIIIB-VIIIB illustrated in FIG. 8A.

FIG. 8B shows that the absorption-reducing contact electrode 0817 and the upper driving contact electrode 0811 each have a comb-like shape and are independent of each other.

The segments of the upper driving contact electrode 0811 each have a width of 8 μm and are arranged at a pitch of 15 μm. The segments of the absorption-reducing contact electrode 0817 extending between the segments of the upper driving contact electrode 0811 each have a width of 10 μm.

FIG. 8C is a sectional view of the laser taken in an xy plane extending along line VIIIB-VIIIB illustrated in FIG. 8A.

In the third exemplary embodiment, the widths of the segments of the upper driving pad electrode 0812 and the absorption-reducing pad electrode 0818 are the same as the widths of the segments of the upper driving contact electrode 0811 and the absorption-reducing contact electrode 0817, respectively.

In the laser according to the third exemplary embodiment, the diameter of each hole provided in a photonic crystal layer 0806 is 60 nm, which is different from that of the first exemplary embodiment. Accordingly, the coupling coefficient κ is about 300, allowing light beams traveling at larger distance from each other to easily couple each other. Therefore, in the third exemplary embodiment, the pitch of the segments of the upper driving contact electrode 0811 is larger than the pitch of the upper contact electrodes 0711 according to the first exemplary embodiment.

The angle formed between the direction of each lattice vector of the photonic crystal and the longitudinal direction of the segments of the upper driving contact electrode 0811 is 45°, as with that of the first exemplary embodiment.

In the laser according to the third exemplary embodiment, an effect of lowering the threshold current of the laser without removing any portions of the active layer 0804 is produced by injecting a current for reduction of light absorption by the active layer 0804 in addition to the driving current. Materials forming the laser and other factors according to the third exemplary embodiment are all the same as those of the first exemplary embodiment.

The laser according to the third exemplary embodiment is manufactured by the same method as in the first exemplary embodiment, except the pattern of a mask to be used in forming the upper electrodes.

### Fourth Exemplary Embodiment

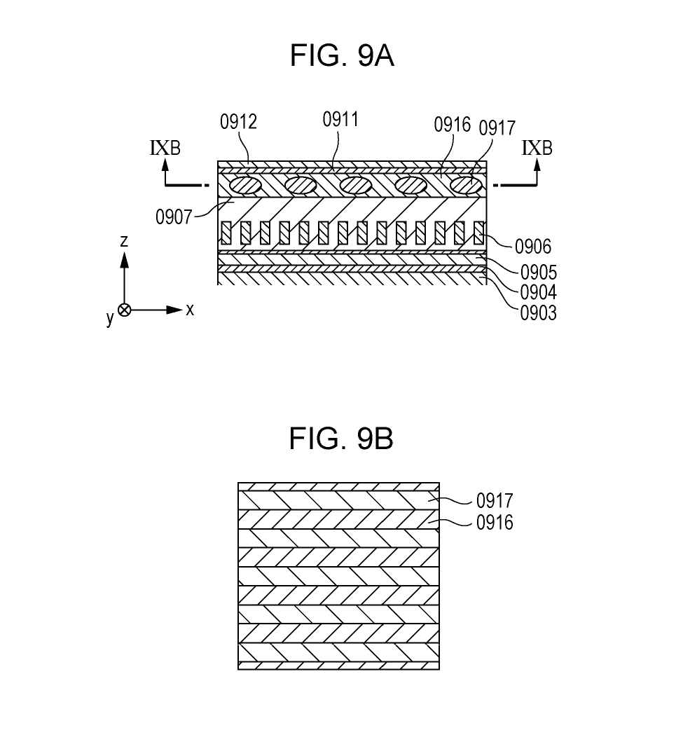

A configuration of a surface emitting laser according to a fourth exemplary embodiment that is different from that of the first exemplary embodiment will now be described with reference to FIGS. 9A and 9B.

FIG. 9A is a schematic sectional view mainly illustrating an upper portion of the laser according to the fourth exemplary embodiment including an active layer 0904 and layers provided thereabove.

In the fourth exemplary embodiment, an upper contact electrode 0911 has a flat plate-like shape, instead of having a stripe pattern, extending over the entirety of a photonic crystal region.

Therefore, none of the insulating members provided between the upper contact electrodes according to the other exemplary embodiments are provided in the fourth exemplary embodiment. Instead, high-resistance regions 0917 each having a high resistance are provided below the upper contact electrode 0911. In the fourth exemplary embodiment, the high-resistance regions 0917 are embedded in a contact layer 0916.

FIG. 9B is a sectional view of the laser taken in an xy plane extending along line IXB-IXB illustrated in FIG. 9A.

In the fourth exemplary embodiment, the high-resistance regions 0917 each have a width of 10 μm and are arranged in a strip pattern, as illustrated in FIG. 9B, at a pitch of 15 μm.

In the fourth exemplary embodiment, the upper contact electrode 0911 has a flat plate-like shape, and the current is less injectable into the high-resistance regions 0917. Therefore, regions of the laser immediately below the high-resistance regions 0917 each have a low current density.

Hence, electricity is supplied to regions forming a stripe pattern. Thus, the regions to which electricity is supplied are classified into regions for absorption reduction and regions for driving, as in the third exemplary embodiment.

The current density in the regions to which a current for absorption reduction is injected is controllable by controlling the resistance of the high-resistance regions 0917. If the high-resistance regions 0917 are designed as completely insulating regions, no electricity is supplied to the high-resistance regions 0917, producing the same effect as in the first exemplary embodiment.

The laser according to the fourth exemplary embodiment is manufactured by the same method as in the first exemplary embodiment, except an additional step of forming the high-resistance regions 0917.

The high-resistance regions 0917 are formed by ion implantation or the like.

In the fourth exemplary embodiment, after forming the layers up to the contact layer 0916, the step of forming the high-resistance regions 0917 is performed by photolithography and ion implantation.

The other configurations and materials of the laser according to the fourth exemplary embodiment are the same as those employed in the third exemplary embodiment.

The first to fourth exemplary embodiments described above are only for exemplary. The materials, size, shape, and other factors that define the elements included in the laser according to the embodiments are not limited in any way to those employed in the above exemplary embodiments.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2012-140591, filed Jun. 22, 2012, which is hereby incorporated by reference herein in its entirety.

What is claimed is:

1. A surface emitting laser comprising:
an active layer;
a periodic-structure layer including a low-refractive-index medium and a high-refractive-index medium and whose refractive index varies two-dimensionally and periodically, the periodic-structure layer being provided at a position where light emitted from the active layer couples therewith; and
a pair of electrodes from which electricity is supplied to the active layer,
wherein the periodic-structure layer is patterned as a square periodic-structure lattice,
wherein at least one of the electrodes includes one or more linear electrodes, and
wherein a direction of each lattice vector of the periodic structure and a longitudinal direction of the linear electrodes are different from each other.

2. The surface emitting laser according to claim 1, further comprising a current injection region into which a current is injected from the one of the electrodes, the current injection region including one or more linear regions provided side by side in a plane parallel to the active layer.

3. The surface emitting laser according to claim 1,
wherein the current from the one of the electrodes is injected into a first region and a second region at respectively different current densities, and
wherein an optical gain obtained at the higher one of the current densities is isotropic in the direction of each lattice vector of the periodic structure and is equal for resonant light that travels in the direction of each lattice vector of the periodic structure.

4. The surface emitting laser according to claim 1,
wherein the one of the electrodes includes two or more linear electrodes which are arranged in a stripe pattern in one direction, and
wherein an angle θ formed between a longitudinal direction of the linear electrodes arranged in the stripe pattern and the direction of each lattice vector of the periodic structure falls within a range of 45-22.5°≦θ≦45+22.5°.

5. The surface emitting laser according to claim 1, wherein the one of the electrodes includes two or more linear electrodes which are arranged in each of two directions such that the linear electrodes form a lattice pattern.

6. The surface emitting laser according to claim 5, wherein the two directions in which the linear electrodes extend in the lattice pattern are orthogonal to each other.

7. The surface emitting laser according to claim 4,
wherein a region where the periodic structure is provided is a square of side L,
wherein the stripe pattern of the linear electrodes is periodical, and
wherein the angle θ is 45°, and
wherein the surface emitting laser satisfies the following condition:
√2N(W₁+W₂)=L
where W₁ denotes a width of each of the linear electrodes, W₂ denotes a pitch of the linear electrodes in a direction in which the linear electrodes are arranged periodically, and N is a positive integer.

8. The surface emitting laser according to claim 5,
wherein a region where the periodic structure is provided is a square of side L,
wherein the lattice pattern of the linear electrodes is periodical, and
wherein a angle θ formed between a longitudinal direction of the linear electrodes arranged in the lattice pattern and the direction of each lattice vector of the periodic structure is 45°, and
wherein the surface emitting laser satisfies the following condition:
√2N(W₁+W₂)=L
where W₁ denotes a width of each of the linear electrodes, W₂ denotes a pitch of the linear electrodes in a direction in which the linear electrodes are arranged periodically, and N is a positive integer.

9. The surface emitting laser according to claim 1,
wherein, assuming the linear electrodes to be first electrodes, a second electrode that reduces light absorption loss due to the active layer is provided in a region that is free of the first electrodes, and
wherein a density of the current injected from the second electrode is lower than a density of the current injected from the first electrodes.

10. The surface emitting laser according to claim 1, wherein, assuming the linear electrodes to be first electrodes, the active layer is absent at positions corresponding to any regions that are free of the first electrodes.

11. A surface emitting laser comprising:
an active layer;
a periodic-structure layer provided at a position where light emitted from the active layer couples therewith and including a low-refractive-index medium and a high-refractive-index medium; and
a pair of electrodes from which electricity is supplied to the active layer,
wherein the periodic-structure layer is patterned as a square periodic-structure lattice,
wherein at least one of the electrodes includes island electrodes arranged in a pattern that is reverse to a lattice pattern formed by two or more lines extending in each of two directions, and
wherein a direction of each lattice vector of the periodic structure and a direction of each lattice vector of the lattice pattern of the island electrodes are different from each other.

12. The surface emitting laser according to claim 11,
wherein, assuming the island electrodes to be first electrodes, a second electrode that reduces light absorption loss due to the active layer is provided in a region that is free of the first electrodes, and
wherein a density of the current injected from the second electrode is lower than a density of the current injected from the first electrodes.

13. The surface emitting laser according to claim 11, wherein, assuming the island electrodes to be first electrodes, the active layer is absent at positions corresponding to any regions that are free of the first electrodes.
